(19) United States
(12) Patent Application Publication
(10) Pub. No.: US 2012/0056867 A1
(43) Pub. Date: Mar. 8, 2012

(54) SYSTEM AND METHOD OF LEAKAGE CURRENT COMPENSATION WHEN SENSING STATES OF DISPLAY ELEMENTS

(75) Inventors: Wilhelmus Johannes Robertus Van Lier, San Diego, CA (US); Didier H. Farenc, San Diego, CA (US)

(73) Assignee: Qualcomm Mems Technologies, Inc., San Diego, CA (US)

(21) Appl. No.: 13/224,786

(22) Filed: Sep. 2, 2011

Related U.S. Application Data
(60) Provisional application No. 61/380,187, filed on Sep. 3, 2010.

(51) Int. Cl. G09G 5/00; G01R 31/44

(52) U.S. Cl. 345/212; 324/403

(57) ABSTRACT

This disclosure provides systems, methods and apparatus for calibrating display arrays. A leakage compensation circuit is provided in conjunction with a circuit for sensing display element states. The leakage compensation circuit may include a leakage current integrator and a voltage to current converter.

### CROSS-REFERENCE TO RELATED APPLICATIONS

This disclosure claims priority under 35 U.S.C. §119(e) to U.S. Provisional Patent Application No. 61/380,187, filed Sep. 3, 2010, which is hereby incorporated by reference in its entirety.

### TECHNICAL FIELD

This disclosure relates to leakage current compensation when testing display element states in a display array.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of compensating for leakage current during a state sensing test in a display array. The method may include connecting one or more common lines to be tested to a leakage compensation circuit, generating a compensating current in the leakage compensation circuit; and connecting both the one or more common lines to be tested and the leakage compensation circuit to a state sensing circuit. The method may include integrating the leakage current to produce a voltage. The method may also include converting the voltage to a leakage compensation current.

In another aspect, an apparatus for calibrating drive scheme voltages is provided. The apparatus may include an array of display elements arranged into one or more rows. The apparatus may further include one or more lines in the array, each line connecting display elements along a respective row of the one or more rows. The apparatus may further include driver circuitry connected to the one or more lines in the array, display element state sensing circuitry coupled to the one or more lines in the array, and a leakage compensation circuit coupled to the one or more lines in the array.

In another aspect, an apparatus for calibrating a display is provided that includes an array of display elements, a driver circuit coupled to the array of display elements, means for sensing display element states, and means for compensating for leakage current when sensing display element states.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 is a block diagram illustrating examples of a common driver and a segment driver for driving an implementation of a 64 color per pixel display.

FIG. 10 shows an example of a diagram illustrating movable reflective mirror position versus applied voltage for several members of an array of interferometric modulators.

FIG. 11 is a schematic block diagram of a display array coupled to driver circuitry and state sensing circuitry.

FIG. 12 is a schematic diagram showing test charge flow in the array of FIG. 11.

FIG. 13 is a schematic diagram of one example of a leakage compensation circuit coupled to one or more common lines under test.

FIG. 14 is a schematic diagram of one implementation of the voltage-to-current converter of FIG. 13.

FIG. 15 is flowchart of one example of a method of leakage compensation.

FIGS. 16A and 16B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

In some drive scheme implementations, the process of writing information to a pixel is accomplished by applying drive scheme voltages across the pixel that are sufficient to actuate the pixel, release the pixel, or hold the pixel in its current state. Because the voltages which actuate and release the pixels may be different for different display elements, determination of appropriate drive scheme voltages to avoid artifacts in displaying an image can be difficult.

The task of determining appropriate drive scheme voltages can be further complicated by the fact that the voltages which actuate and release the pixels can change through the life of the display, e.g., with wear or with a change in temperature. Accurately measuring these values by examining the entire array to update the drive scheme voltages may be time-consuming. Thus, in some implementations, drive scheme voltages are dynamically updated based on measurements of subsets of the entire array. For example, in some implementations, updated drive scheme voltages are determined based on measurements of a representative line or set of lines.

Particular implementations of the subject matter described in this disclosure can be implemented to realize one or more of the following potential advantages. Implementations described herein allow for more accurate state sensing when updating drive scheme voltages in a display array. Because of driver circuit leakage current, a capacitive state sensor can exhibit an error. In some implementations, a leakage current compensation circuit is utilized to cancel out this leakage current. More accurate state sensing allows for the selection of more optimal drive scheme voltages, thus reducing perceptible artifacts in the display over the life of the display and in varying environmental conditions.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

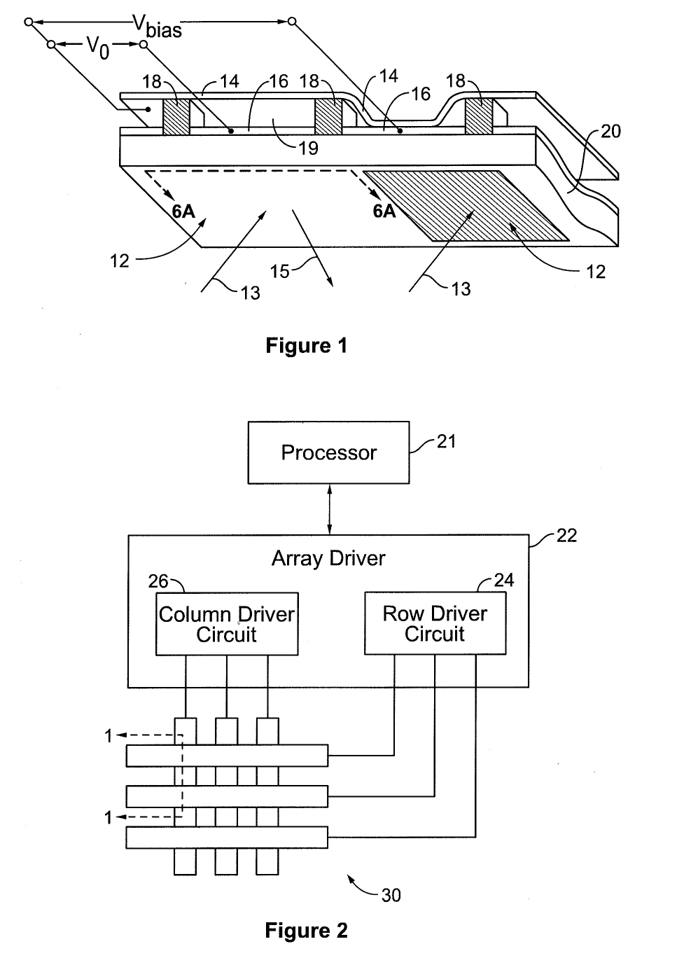

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be about 1-1000 um, while the gap 19 may be less than about 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

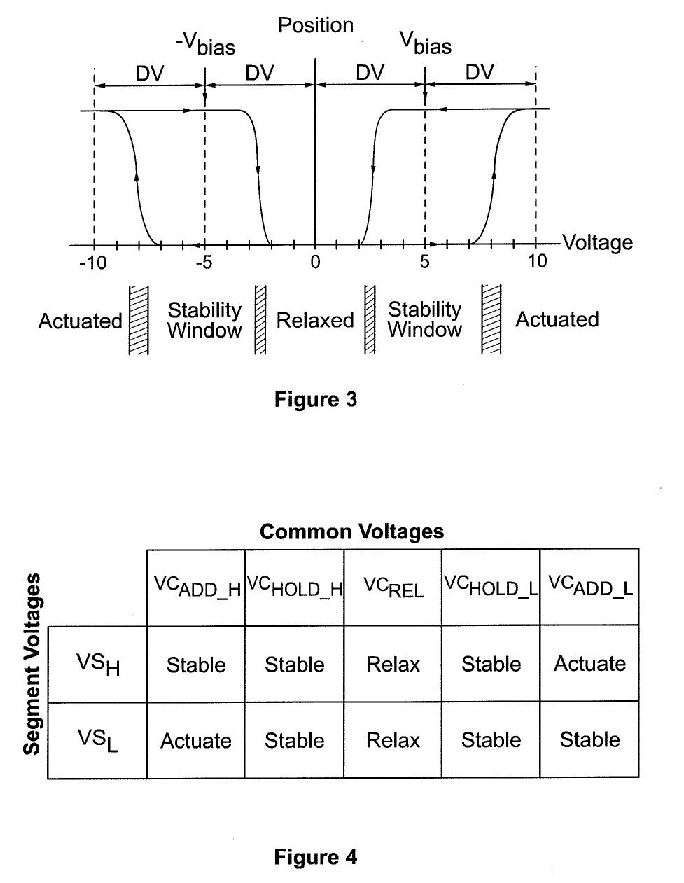

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

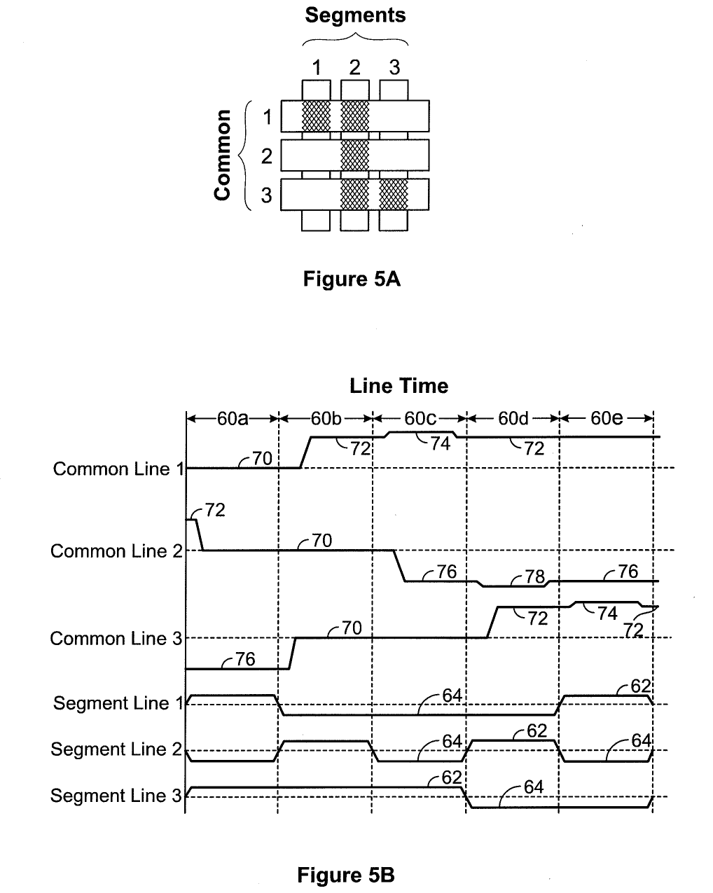

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

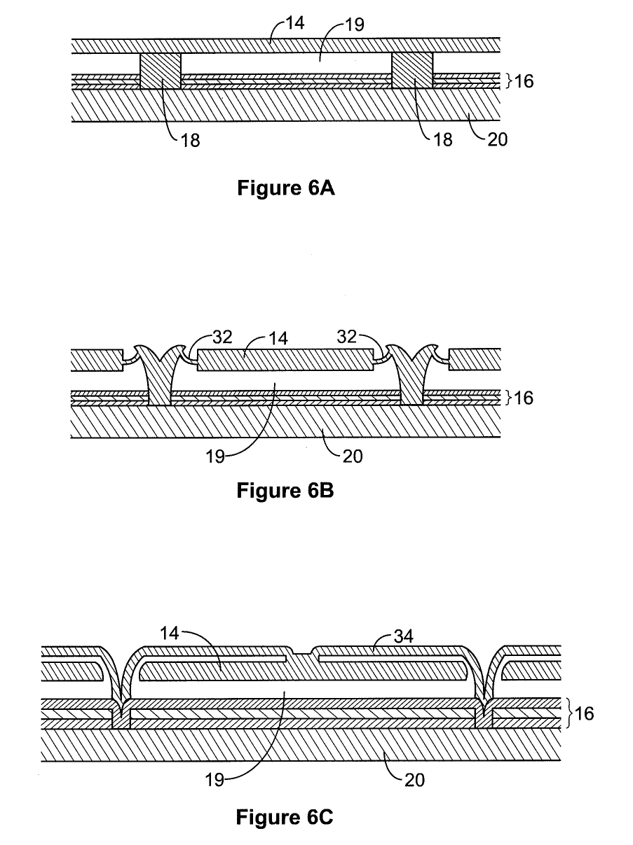

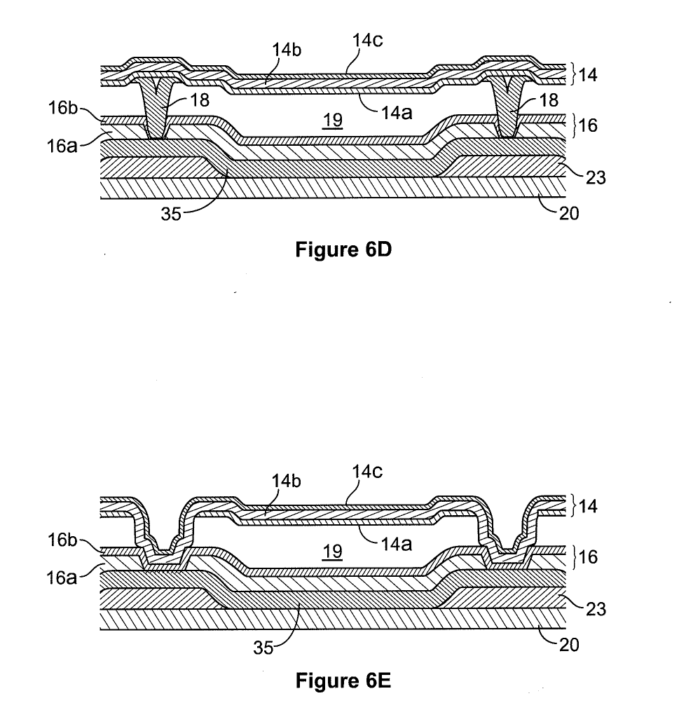

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

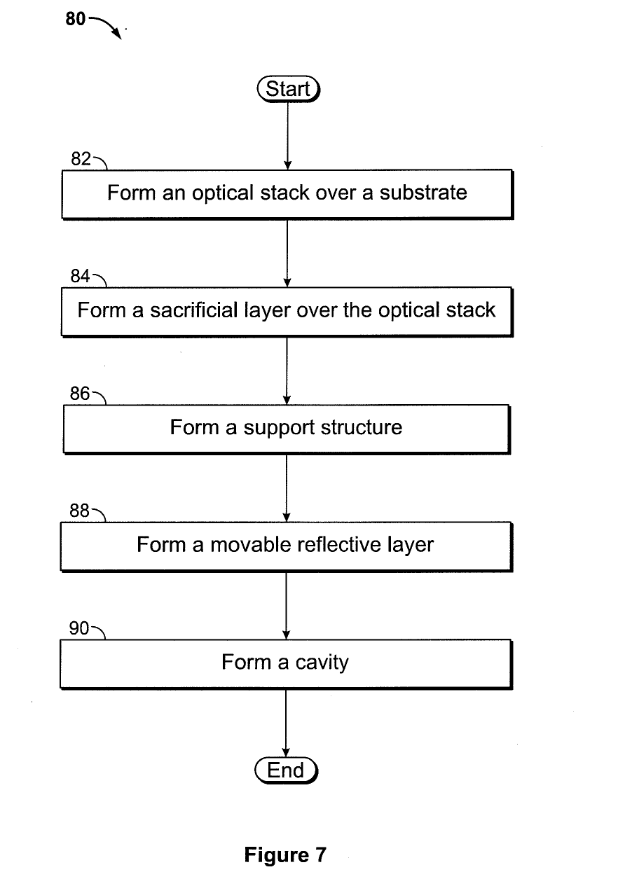

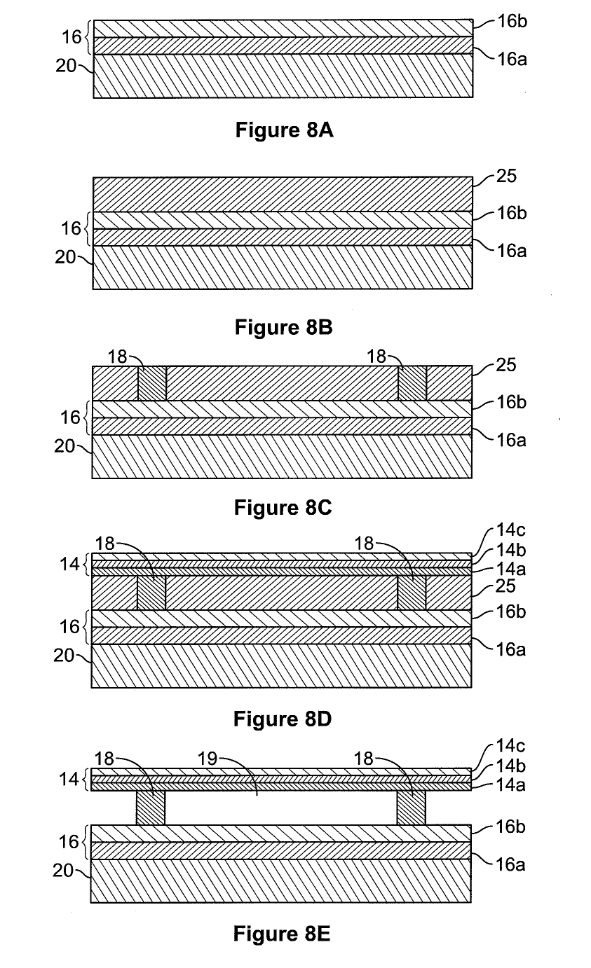

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

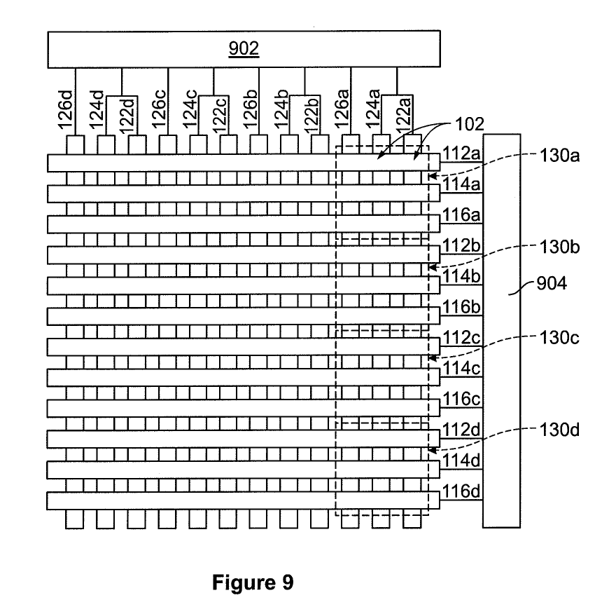

FIG. 9 is a block diagram illustrating examples of a common driver 904 and a segment driver 902 for driving an implementation of a 64 color per pixel display. The array can include a set of electromechanical display elements 102, which in some implementations may include interferometric modulators. A set of segment electrodes or segment lines 122a-122d, 124a-124d, 126a-126d and a set of common electrodes or common lines 112a-112d, 114a-114d, 116a-116d can be used to address the display elements 102, as each display element will be in electrical communication with a segment electrode and a common electrode. Segment driver 902 is configured to apply voltage waveforms across each of the segment electrodes, and common driver 904 is configured to apply voltage waveforms across each of the column electrodes. In some implementations, some of the electrodes may be in electrical communication with one another, such as segment electrodes 122a and 124a, such that the same voltage waveform can be simultaneously applied across each of the segment electrodes. Because it is coupled to two segment electrodes, the segment driver outputs connected to two segment electrodes may be referred to herein as a “most significant bit” (MSB) segment output since the state of this segment output controls the state of two adjacent display elements in each row. Segment driver outputs coupled to individual segment electrodes such as at 126a may be referred to herein as “least significant bit” (LSB) electrodes since they control the state of a single display element in each row.

Still with reference to FIG. 9, in an implementation in which the display includes a color display or a monochrome grayscale display, the individual electromechanical elements 102 may include subpixels of larger pixels. Each of the pixels may include some number of subpixels. In an implementation in which the array includes a color display having a set of interferometric modulators, the various colors may be aligned along common lines, such that substantially all of the display elements along a given common line include display elements configured to display the same color. Some implementations of color displays include alternating lines of red, green, and blue subpixels. For example, lines 112a-112d may correspond to lines of red interferometric modulators, lines 114a-114d may correspond to lines of green interferometric modulators, and lines 116a-116d may correspond to lines of blue interferometric modulators. In one implementation, each 3×3 array of interferometric modulators 102 forms a pixel such as pixels 130a-130d. In the illustrated implementation in which two of the segment electrodes are shorted to one another, such a 3×3 pixel will be capable of rendering 64 different colors (e.g., a 6-bit color depth), because each set of three common color subpixels in each pixel can be placed in four different states, corresponding to none, one, two, or three actuated interferometric modulators. When using this arrangement in a monochrome grayscale mode, the state of the three pixel sets for each color are made to be identical, in which case each pixel can take on four different gray level intensities. It will be appreciated that this is just one example, and that larger groups of interferometric modulators may be used to form pixels having a greater color range with different overall pixel count or resolution.

As described in detail above, to write a line of display data, the segment driver 902 may apply voltages to the segment electrodes or buses connected thereto. Thereafter, the common driver 904 may pulse a selected common line connected thereto to cause the display elements along the selected line to display the data, for example by actuating selected display elements along the line in accordance with the voltages applied to the respective segment outputs.

After display data is written to the selected line, the segment driver 902 may apply another set of voltages to the buses connected thereto, and the common driver 904 may pulse another line connected thereto to write display data to the other line. By repeating this process, display data may be sequentially written to any number of lines in the display array.

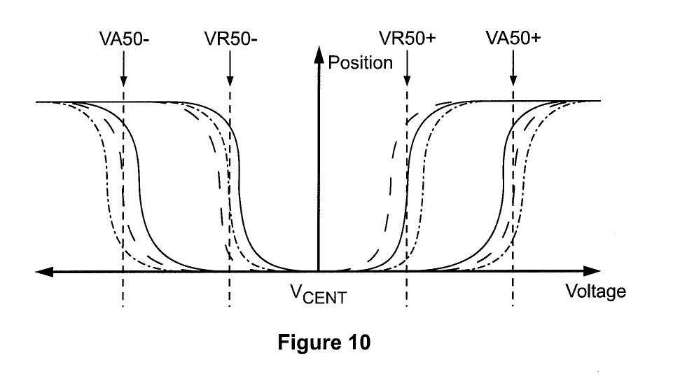

FIG. 10 shows an example of a diagram illustrating movable reflective mirror position versus applied voltage for several members of an array of interferometric modulators. FIG. 10 is similar to FIG. 3, but illustrates variations in hysteresis curves among different modulators in the array. Although each interferometric modulator generally exhibits hysteresis, the edges of the hysteresis window are not at identical voltages for all modulators of the array. Thus, the actuation voltages and release voltages may be different for different interferometric modulators in an array. In addition, the actuation voltages and release voltages can change with variations in temperature, aging, and use patterns of the display over its lifetime. This can make it difficult to determine voltages to be used in a drive scheme, such as the drive scheme described above with respect to FIG. 4. This can also make it useful for optimal display operation to vary the voltages used in a drive scheme in a manner that tracks these changes during use and over the life of the display array.

Returning now to FIG. 10, at a positive actuation voltage above a center voltage (denoted V_{CENT} in FIG. 10) and at a negative actuation voltage below the center voltage, each interferometric modulator changes from a released state to an actuated state. The center voltage is the midpoint between the positive hysteresis window and the negative hysteresis window. It can be defined in a variety of ways, e.g. halfway between the outer edges, halfway between the inner edges, or halfway between the midpoints of the two windows. For an array of modulators, the center voltage may be defined as the average center voltage for the different modulators of the array, or may be defined as midway between the extremes of the hysteresis windows for all the modulators. For example, with reference to FIG. 10, the center voltage may be defined as midway between the high actuation voltage and the low actuation voltage. As a practical matter, it is not particularly important how this value is determined, since the center voltage for an interferometric modulator is typically close to zero, and even when this is not the case, the various methods of calculating a midpoint between hysteresis windows will arrive at substantially the same value. In those implementations where the center voltage may is offset from zero, this deviation may be referred to as the voltage offset.

As described above, these values are different for different interferometric modulators. It is possible to characterize an approximate median positive and negative actuation voltage for the array, designated VA50+ and VA50− respectively in FIG. 10. The voltage VA50+ can be characterized as the positive polarity voltage that would cause about 50% of the modulators of an array to actuate. The voltage VA50− can be characterized as the negative polarity voltage that would cause about 50% of the modulators of an array to actuate. Using this terminology, the center voltage V_{CENT} may be defined as (VA50++VA50−)/2.

Similarly, at a positive polarity release voltage above the center voltage and at a negative polarity release voltage below the center voltage, the interferometric modulator changes from the actuated state to the released state. As with the positive and negative actuation voltages, it is possible to characterize an approximate middle or average positive and negative release voltage for the array, designated VR50+ and VR50− respectively in FIG. 10.

These average or representative values for the array can be used to derive drive scheme voltages for the array. In some implementations, a positive hold voltage (designated 72 in FIG. 5B) may be derived as the average of VA50+ and VR50+. A negative hold voltage (designated 76 in FIG. 5B) may be derived as the average of VA50− and VR50−. This puts the positive and negative hold voltages at approximately the center of a typical or average hysteresis window of the array. The positive and negative segment voltages (designated 62 and 64 in FIG. 5B, and referred to herein as VS+ and VS−) may be derived as the average of the two window widths, defined respectively as (VA50+−VR50+) and (VA50−−VR50−), divided by four. This sets the segment voltage magnitudes at approximately ¼ of the width of a typical or average hysteresis window of the array, with the actual segment voltages VS+ and VS− being the positive and negative polarities of this magnitude. In some implementations, the actuation voltage applied to the common lines (designated 74 in FIG. 5B) is derived as the hold voltage plus twice the segment voltage. In some implementations, an additional empirically determined value V_{adj} is added to the positive hold voltage and subtracted from the negative hold voltage computation described above. Although not always necessary, this can help avoid having portions of the display fail to actuate when desired during image data writing, which can be especially visible to the user in some cases. This additional parameter V_{adj} essentially moves the hold voltages slightly closer to the outer actuation edges of the hysteresis curves which helps ensure actuation of all display elements. If V_{adj} is too large, however, excessive false actuations may occur. In some implementations, values for VA50+ and VA50− may be in the 10-15 volt range. Values for VR50+ and VR50− may be in the 3-5 volt range. If, for example, measurements indicated a VA50+ of 12V, a VA50− of −12V, a VR50+ of 4V, and a VR50− or −4V, the above computations would set the positive and negative hold voltages at +8 and −8 volts respectively (if V_{adj} is zero), and the segment voltages would be +2V and −2V. An interferometric modulator being actuated during a write pulse would have a voltage of 8+3*2 V applied across it, which is 14 V, which may reliably actuate essentially any display element of the array if the median actuation voltage is 12V. One of ordinary skill in the art would appreciate that the above voltages may vary in different implementations.

When the array is a color array having different common lines of different colors as described above with reference to FIG. 9, it can be useful to use different hold voltages for different color lines of display elements. Because different color interferometric modulators have different mechanical constructions, there may be a wide variation in hysteresis curve characteristics for interferometric modulators of different colors. Within the group of modulators of one color of the array, however, more consistent hysteresis properties may be present. For a color display, different values for VA50+, VA50−, VR50+, and VR50− can be measured for each color of display elements of the array. For a three color display, this is twelve different display response characteristics. In these implementations, positive and negative hold voltages for each color can be separately derived as described above using the four values of VA50+, VA50−, VR50+, and VR50− measured for that color. Because the segment voltages are applied along all the rows, a single segment voltage for all colors may be derived. This may be derived similar to the above, where an average hysteresis window width over both polarities and all colors is computed, and then divided by four. An alternative computation for a segment voltage may include computing a segment voltage for one or more colors separately as described above, and then selecting one of these (e.g. the smallest magnitude, the middle magnitude, the one from a particular color with visual significance, etc.) as the segment voltage for the entire array.

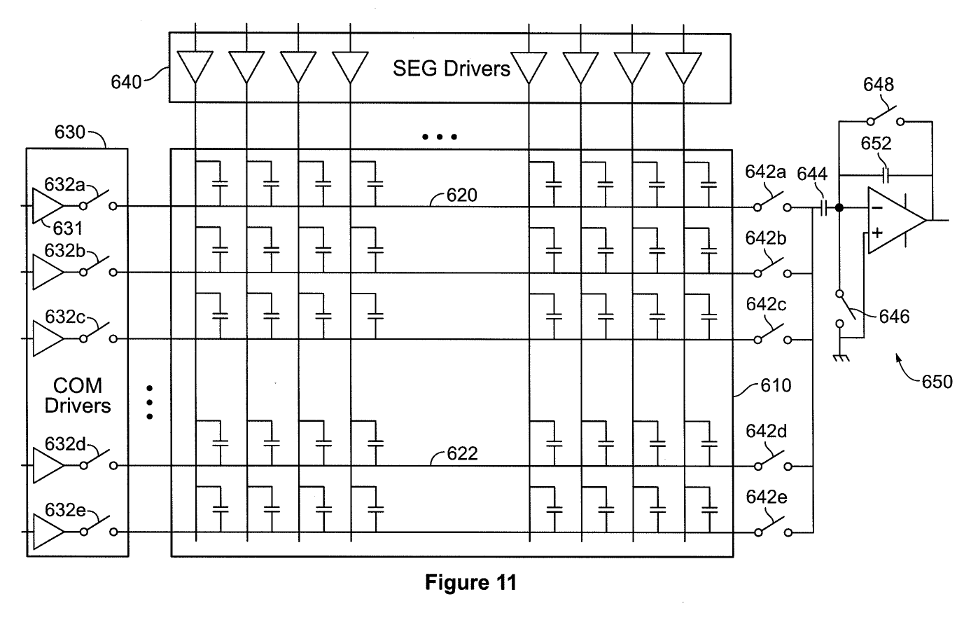

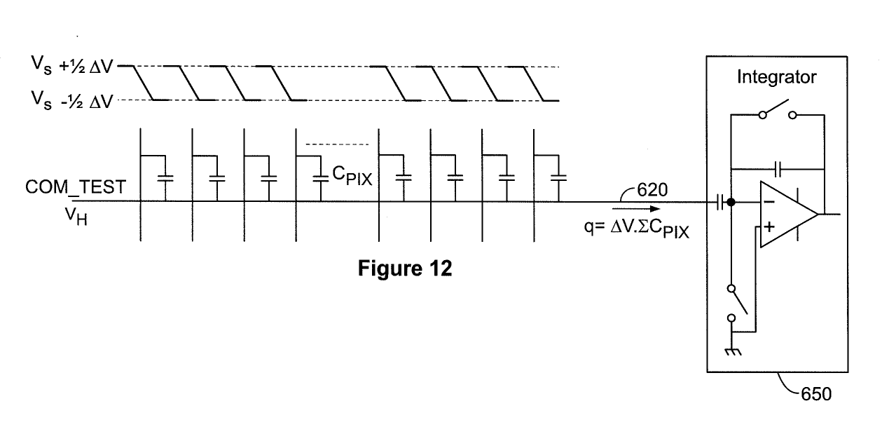

As mentioned above, the values for VA50+, VA50−, VR50+, and VR50− may vary between different arrays due to manufacturing tolerances, and may also vary in a single array with temperature, over time, depending on use, and the like. To initially set and later adjust these voltages to produce a display that functions well over its lifetime it is possible to incorporate testing and state sensing circuitry into a display apparatus. This is illustrated in FIGS. 11 and 12.

FIG. 11 is a schematic block diagram of a display array coupled to driver circuitry and state sensing circuitry. In this apparatus, a segment driver circuit 640 and a common diver circuit 630 are coupled to a display array 610. The display elements are illustrated as capacitors connected between respective common and segment lines. For interferometric modulators, the capacitance of the device may be about 3-10 times higher in the actuated state when the two electrodes are pulled together than it is in the released state, when the two electrodes are separated. This capacitance difference can be detected to determine the state or states of one or more display elements.

In the implementation of FIG. 11, the detection is done with an integrator 650. The function of the integrator is described with further reference to FIG. 12, which is a schematic diagram showing test charge flow in the array of FIG. 11. Referring now to FIG. 11 and FIG. 12, the common driver circuit 630 of FIG. 11 includes switches 632a-632e that connect test output drivers 631 to one side of one or more common lines. Another set of switches 642a-642e connect the other ends of one or more common lines to an integrator circuit 650.

As one example test protocol, each segment driver output could be set to a voltage, VS+, for example. Switches 648 and 646 of the integrator are initially closed. To test line 620, for example, switch 632a and switch 642a are closed, and a test voltage is applied to the common line 620, charging the capacitive display elements and an isolation capacitor 644. Then, switch 632a, 648, and 646 are opened, and the voltages output from the segment drivers are changed by an amount ΔV. The charge on the capacitors formed by the display elements is changed by an amount equal to about ΔV times the total capacitance of all the display elements. This charge flow from the display elements is converted to a voltage output by the integrator 650 with integration capacitor 652, such that the voltage output of the integrator is a measure of the total capacitance of the display elements along the common line 620.

This can be used to determine the parameters VA50+, VA50−, VR50+ and VR50− for a line of display elements being tested. To accomplish this, a first test voltage is applied that is known to release all of the display elements in the line. This may be 0 volts for example. In this instance, the total voltage across the display elements is VS+, which is, for example, 2V, which is within the release window of all the display elements. The output voltage of the capacitor when the segment voltages are modulated by ΔV is recorded. This integrator output may be referred to as Vₘᵢₙ for the line, which corresponds to the lowest line capacitance Cₘᵢₙ of the line. This is repeated with a common line test voltage that is known to actuate all of the display elements in the line, for example 20V. This integrator output may be referred to as Vₘₐₓ for the line, which corresponds to the highest line capacitance Cₘₐₓ of the line.

To determine VA50+ (positive polarity being defined here as common line at higher potential than segment line), the display elements of the line are first released with a low voltage, such as 0V on the common line. Then, a test voltage between 0V and 20V is applied. If the difference between the test voltage and the segment voltage is at VA50+, then the output of the integrator will be (Vₘₐₓ+Vₘᵢₙ)/2.

Since there may be no prior knowledge of the correct value for VA50+, it can be found efficiently with a binary search for the correct test voltage in some implementations. For instance, if VA50+ is exactly 12V, then the proper test voltage will be 14V, which will produce 12V across the display elements when the segment voltage is 2V as discussed in the example above. To run a binary search, the first test voltage can be the midpoint between the low and high voltages of 0V and 20V, which is 10V. When 10V test voltage is applied and the segment voltages are modulated, the integrator output will be less than (Vₘₐₓ+Vₘᵢₙ)/2, which indicates that 10V is too low. In a binary search, each next “guess” is halfway between the last value known to be too low and the last value known to be too high. Thus, the next voltage attempt will be midway between 10V and 20V, which is 15V. When 15V test voltage is applied and the segment voltages are modulated, the integrator output will be more than (Vₘₐₓ+Vₘᵢₙ)/2, which indicates that 15V is too high. Repeating the binary search algorithm, the next test voltage will be 12.5V. This will produce an integrator output that is too low, and the next test voltage will be 13.75V. This process can continue until the integrator output and test voltage are as close as desired to the actual values of (Vₘₐₓ+Vₘᵢₙ)/2 and 14V. In practice, eight iterations are almost always sufficient to determine VA50+ as the last applied test voltage minus the applied segment voltage. The search can be terminated prior to eight iterations if the integrator output is sufficiently close to (Vₘₐₓ+Vₘᵢₙ)/2, for example, within 10% or within 1% of the (Vₘₐₓ+Vₘᵢₙ)/2 target value. To determine VA50− the process is repeated with negative test voltages applied to the common line. VR50+ and VR50− may be determined in an analogous manner, but the display elements are first actuated prior to each test, rather than released.

During manufacture of the array, this process can be performed on each line of the array to determine the parameters VA50+, VA50−, VR50+, and VR50− for each line. For a monochrome array, the values of VA50+, VA50−, VR50+, and VR50− for the array can be the average of the determined values for each line, and drive scheme voltages can be derived for the array as described above. For a color array, the values can be grouped by color, and drive scheme voltages for the array can also be derived as described above.

During use of such an array, it would be possible to repeat the above described process for each line and derive new drive scheme voltages that are suitable for the current condition of the array, temperature, etc. However, this can be undesirable because this procedure can take a significant amount of time and be visible to the user. To improve speed and reduce interference with display viewing by a user, the array can be divided into subsets, and only one or more subsets of the array may be tested and characterized. These subsets can be sufficiently representative of the whole array such that the drive scheme voltages derived from these subset measurements are suitable for the whole array. This reduces the time required to perform the measurements, and can allow the process to be performed during use of the array with less inconvenience to the user. Referring back to FIG. 11, for example, a single line 622 of FIG. 11 can be selected as a representative subset of the array for testing and characterization during display use. Periodically during use of the array, switches 632d and 642d are used to test line 622 for VA50+, VA50−, VR50+, and VR50− and the results are used to derive updated drive scheme voltages. In some implementations, line 622 may have been previously determined as a representative line based on measurements of every line made during manufacture as described above. Generally, such a representative line will have values for VA50+, VA50−, VR50+, and VR50− that are close to the average values of VA50+, VA50−, VR50+, and VR50− for all the lines of the array. In some implementations, several lines can be used as representative subsets of the array, and tested either simultaneously or sequentially by controlling switches 632a-632e and 642a-642e.

When the above described test procedures are performed, it is possible that an error can be introduced into the integrator output by leakage current from the common driver circuit 630. This is because even after the switches 632a-632e are opened, the transistors or other switch circuits in the driver 830 have some finite off state impedance. Leakage current through this impedance can also charge the integration capacitor of the integrator 650 during the test procedure, which results in an output voltage of the integrator 650 differing from the voltage produced by just the charge migration caused by modulating the segment voltages.

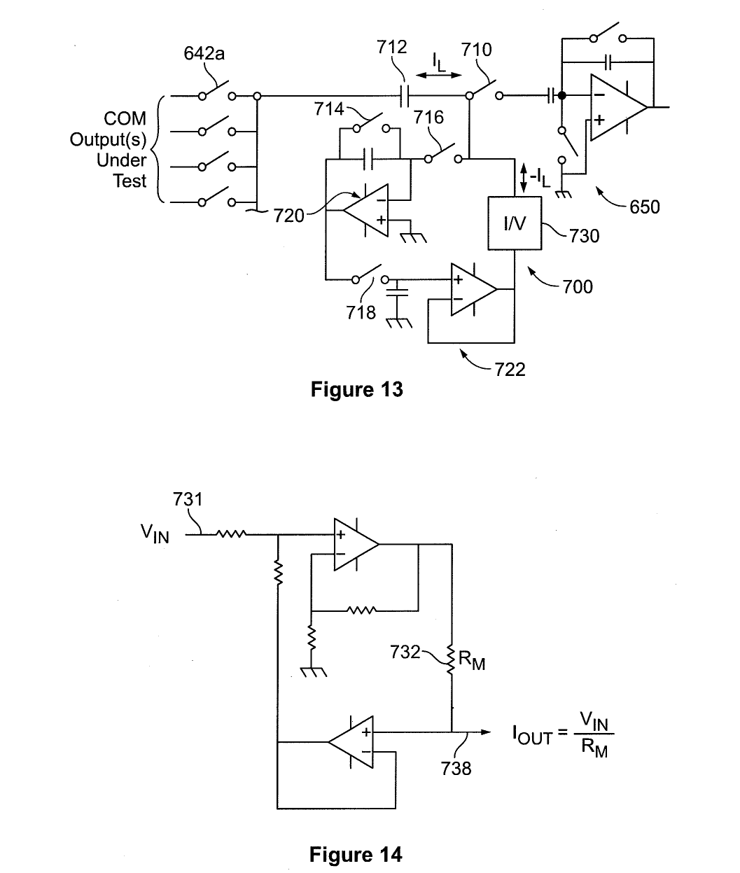

To resolve this problem, a leakage compensation circuit can be coupled to the one or more common lines under test. FIG. 13 is a schematic diagram of one example of a leakage compensation circuit coupled to one or more common lines under test. In this implementation, a leakage compensation circuit 700 is coupled at the input of the state sensing circuit (integrator 650 in this implementation). If, for example, line 620 of FIG. 11 is under test, line 620 is set to the desired test voltage, switch 642a is closed, and switch 632a is opened. As mentioned above, even though switch 632a is opened, leakage current still flows on line 620 acting to charge the isolation capacitor 712. To reduce the effect this leakage current has on the integrator 650 measurement, switch 710 is initially opened, switch 714 is opened, and switches 716 and 718 of the leakage compensation circuit are closed. The leakage current I_{L} then flows into the integration capacitor of integrator 720, producing an inverted voltage output. This output is fed through a buffer 722 to a voltage-to-current converter 730. The current to voltage converter 730 produces a current of opposite direction to the leakage current, and the loop may stabilize when the output current of the voltage to current converter is substantially equal in magnitude and opposite in direction as the leakage current. At this point, the integration capacitor of the integrator 720 is being charged (or discharged) by the leakage current and discharged (or charged) by the output of the voltage to current converter 730 by approximately equal amounts, producing no change to the output of the integrator 720.

Once this loop is stable, switch 716 of the leakage compensation circuit is opened, and switch 710 is closed so that both the line under test 620 and the leakage compensation circuit 700 are connected to the input of the integrator 650. When this occurs, the leakage current flowing into (or out of) the integration capacitor of the integrator 650 is cancelled by the same magnitude but opposite direction current output of the voltage-to-current converter 730. With this implementation, the charge resulting from the modulation of the segment voltages during the test is the only net flow of charge seen by the integrator 650, and the resulting output is an accurate representation of display element capacitance along the line, even in the presence of leakage current from the common line driver 630.

FIG. 14 is a schematic diagram one implementation of the voltage-to-current converter of FIG. 13. Although a variety of implementations are possible, in this example, the voltage input 731 from the buffer 722 is summed with the output voltage of the voltage-to-current converter. The sum is amplified and routed through a resistor 732 having a resistance R_{M}. With this output to input feedback design, the current output 738 by the circuit is the input voltage V_{IN} divided by the resistance R_{M}.

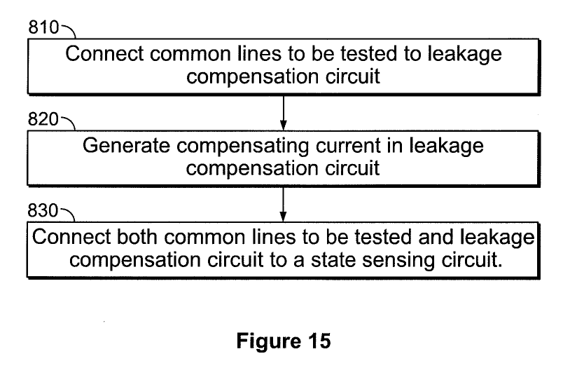

FIG. 15 is flowchart of one example of a method of leakage compensation. The method begins at block 810 where common lines to be tested are connected to a leakage compensation circuit. The method moves to block 820, where a compensating current is generated by the leakage compensation circuit. The method then moves to block 830, where both the common lines to be tested and the leakage compensation circuit are connected to a state sensing circuit. As shown in FIG. 13, this state sensing circuit may be an integrator.

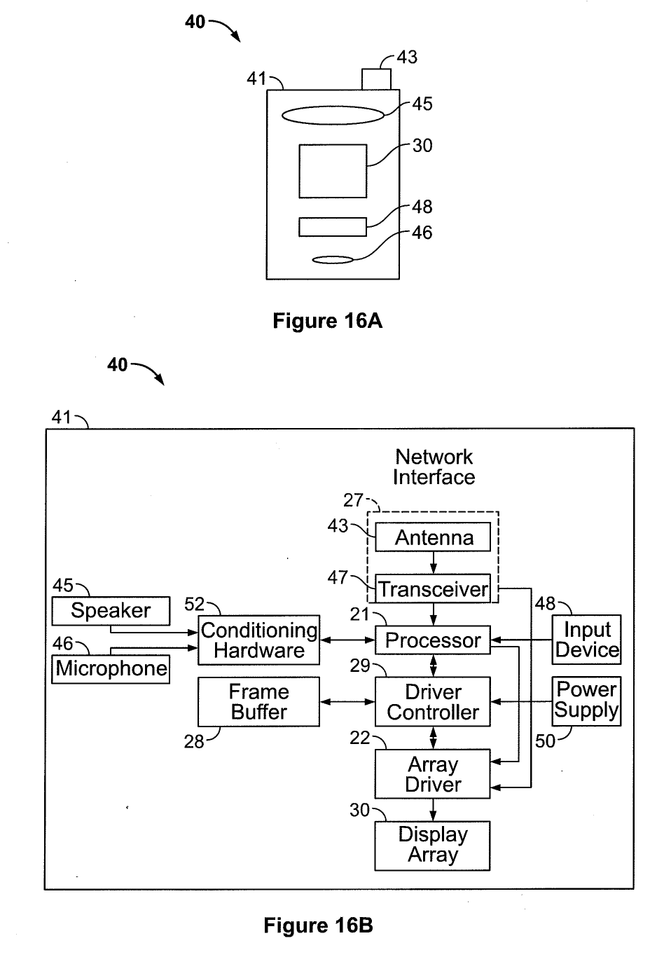

FIGS. 16A and 16B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of compensating for leakage current during a state sensing test in a display array, the method comprising:
connecting one or more common lines to be tested to a leakage compensation circuit;
generating a compensating current in the leakage compensation circuit; and
connecting both the one or more common lines to be tested and the leakage compensation circuit to a state sensing circuit.

2. The method of claim 1, further including integrating the leakage current to produce a voltage.

3. The method of claim 2, further including converting the voltage to a leakage compensation current.

4. The method of claim 3, further including integrating both the leakage current and the leakage compensation current until the voltage is stable.

5. The method of claim 2, wherein the state sensing circuit includes an integrator.

6. An apparatus for calibrating drive scheme voltages, the apparatus comprising:
an array of display elements;
one or more lines in the array, each line connecting display elements along a respective row of the one or more rows;
driver circuitry connected to the one or more lines in the array;
display element state sensing circuitry coupled to the one or more lines in the array; and
a leakage compensation circuit coupled to the one or more lines in the array.

7. The apparatus of claim 6, wherein the leakage compensation circuit includes a leakage current integrator.

8. The apparatus of claim 6, wherein the leakage compensation circuit includes a voltage-to-current converter.

9. The apparatus of claim 8, further comprising:
a processor that is configured to communicate with the array of display elements, the processor being configured to process image data; and
a memory device that is configured to communicate with the processor.

10. The apparatus as recited in claim 9, wherein the driver circuitry is configured to send at least one signal to the array of display elements.

11. The apparatus as recited in claim 10, further comprising:
a controller configured to send at least a portion of the image data to the driver circuit.

12. The apparatus as recited in claim 9, further comprising:
an image source module configured to send the image data to the processor.

13. The apparatus as recited in claim 12, wherein the image source module includes at least one of a receiver, transceiver, and transmitter.

14. The apparatus as recited in claim 9, further comprising:
an input device configured to receive input data and to communicate the input data to the processor.

15. An apparatus for calibrating a display, the apparatus comprising:
an array of display elements;
a driver circuit coupled to the array of display elements;
means for sensing display element states; and
means for compensating for leakage current when sensing display element states.
